(19) United States
(12) Patent Application Publication
(10) Pub. No.: US 2012/0256584 A1
(43) Pub. Date: Oct. 11, 2012

(54) PV monitoring system with combiner switching and charge controller switching

(76) Inventor: David E. Crites, Los Gatos, CA (US)

(21) Appl. No.: 13/440,991

(22) Filed: Apr. 5, 2012

Related U.S. Application Data
(60) Provisional application No. 61/472,137, filed on Apr. 5, 2011.
(60) Provisional application No. 61/483,058, filed on May 6, 2011.

(51) Int. Cl. H02J 7/00; H02B 99/00; G01R 31/00

(52) U.S. Cl. 320/107; 324/750.01; 307/112; 307/113

(57) ABSTRACT

A photovoltaic (PV) monitoring system uses combiner switches and charge controller switches to test the health of a PV installation. Combiner switches are used to direct test current through PV strings and substrings as health measurements are collected by a centralized sensor. Charge controller switches are used to supply test current at night.

### CROSS-REFERENCE TO RELATED APPLICATIONS

This application claims the benefit of prior-filed U.S. Provisional Application No. 61/472,137 filed Apr. 5, 2011 and prior-filed U.S. Provisional Application No. 61/483,058 filed May 6, 2011. This application incorporates-by-reference the monitoring system and methods disclosed in U.S. Non-Provisional Application No. 13/017,002 filed Aug. 29, 2011.

### STATEMENT REGARDING FEDERALLY SPONSORED RESEARCH OR DEVELOPMENT

N/A

### REFERENCE TO SEQUENCE LISTING, A TABLE, OR A COMPUTER PROGRAM LISTING COMPACT DISC APPENDIX

N/A

### FIELD OF THE INVENTION

The invention is related to apparatus and method for testing and monitoring the characteristics and performance of PV installations.

### BACKGROUND OF THE INVENTION

Conventional PV string-monitoring systems situate sensors in the PV combiner boxes where multiple strings converge. Conventional PV module-monitoring systems incorporate sensors in the modules or module junction boxes. In both cases, costly sensor equipment is duplicated. The invention provides a system and method for monitoring a plurality of modules and combiner boxes with fewer sensors than conventional systems by using distributed switches to direct test current to centralized sensor units. The invention also provides a switched charge controller capable of impressing test current through an installed array at night.

### BRIEF DESCRIPTION OF THE DRAWINGS

FIG. 1 illustrates a first embodiment of the PV combiner unit of the invention.

FIG. 2 illustrates a first embodiment of the combiner switching module of FIG. 1.

FIG. 3 illustrates a second embodiment of the combiner switching module of FIG. 1.

FIG. 4 illustrates a second embodiment of the PV combiner unit of the invention.

FIG. 5 illustrates a first embodiment of the combiner switching module of FIG. 4.

FIG. 6 illustrates a second embodiment of the combiner switching module of FIG. 4.

FIG. 7 illustrates a third embodiment of the combiner switching module of FIG. 4.

FIG. 8 illustrates a first embodiment of the sensor unit of the invention.

FIG. 9 illustrates one embodiment of the sensor switching module of FIG. 8.

FIG. 10 illustrates a second embodiment of the sensor unit of the invention.

FIG. 11 illustrates one embodiment of the charge controller unit of the invention.

### SUMMARY OF THE INVENTION

It is the object of the invention to provide a system, comprised of one or more units, capable of monitoring and reporting the active and passive electrical characteristics of the strings, substrings, and modules that comprise PV installations.

It is yet another object of the invention to provide a method for determining and reporting the health of a PV installation by monitoring the active and passive characteristics of its strings, substrings, and modules.

It is yet another object of the invention to provide a system and method for using switches to alter the topology of a PV installation.

It is yet another object of the invention to provide a monitoring system and monitoring methods that use switches and a centralized sensor to monitor a plurality of PV combiner units.

### DETAILED DESCRIPTION

The monitoring system of the invention is comprised of a sensor unit that manages and measures active and passive tests on the strings, substrings, and modules that make up PV power generation circuits; one or more separate PV combiner units that switch the topology of the PV installation in order to give the sensor unit isolated electrical access to one or more strings, substrings, or modules in the installation; an optional charge controller capable of powering the array during night tests, and optionally the networking and general purpose computing resources common in the art. To facilitate multiplexed monitoring, one sensor unit of the invention may connect to one or more PV combiner units of the invention installed in an array topology.

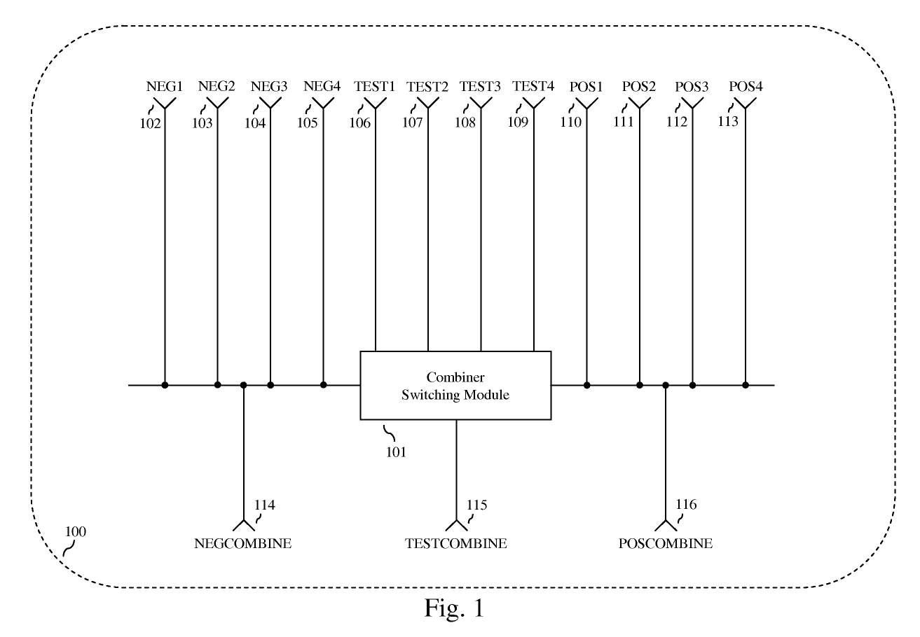

FIG. 1 illustrates one embodiment of the PV combiner unit (100) of the invention. For convenience of illustration, FIG. 1 shows a unit that consolidates the positive ends (110-113), negative ends (102-105), and test harnesses (106-109) of four PV strings, though this embodiment scales to support any practical number of strings. Series monitoring units (described in application Ser. No. 13/017,002), other PV combiner units, or PV conductors may be connected to the test harnesses (106-109) and monitored through the PV combiner unit. NEGCOMBINE (114), TESTCOMBINE (115), and POSCOMBINE (116) pass consolidated PV operating current and consolidated test current to other PV components, including but not limited to, other PV combiner units of the invention, sensor units of the invention, or other components common in the art. The combiner switching module (101) allows a sensor unit of the invention to test individual strings, groups of strings, individual substrings, groups of substrings, individual modules, or groups of modules when the combiner switching module (101) senses a state change or signal on TESTCOMBINE (115). The combiner switching module (101) responds to the state change or signal on TESTCOMBINE (115) by connecting TESTCOMBINE (115) to the individual test harness (106-109) or group of test harnesses (106-109) indicated by the signal, or by connecting TESTCOMBINE (115) to a sequential polling of all or some of the test harnesses (106-109), individually or in groups. NEGCOMBINE (114), NEG1-NEG4 (102-105), POSCOMBINE (116), and POS1-POS4 (110-113) may be excluded from the PV combiner unit of the invention and may thus be combined in a separate conventional combiner box. The PV combiner unit (100) may be powered by any means common in the art, including but not limited to, battery power and the power running through the unit.

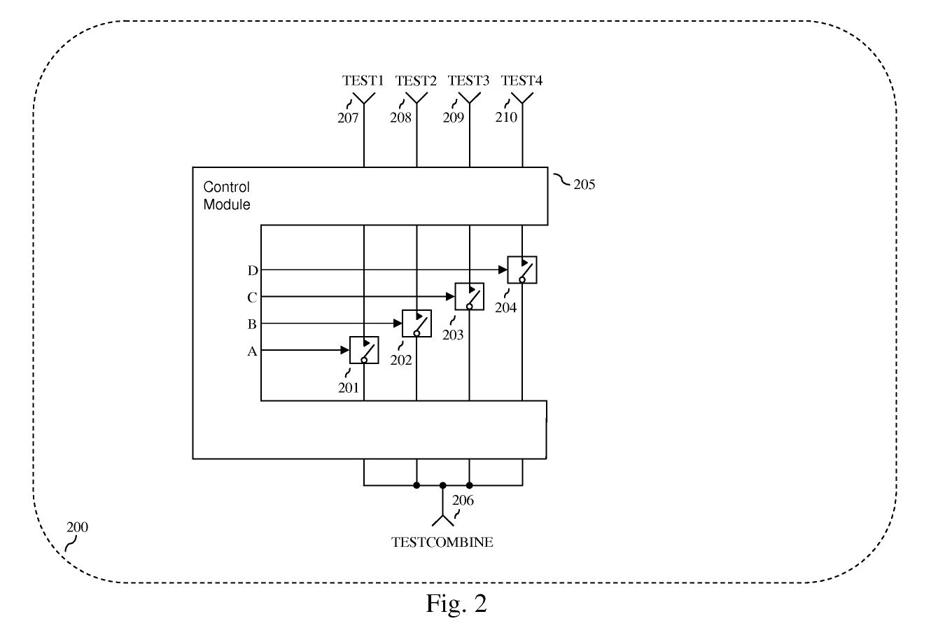

FIG. 2 (200) illustrates a first embodiment of the combiner switching module of FIG. 1 (101). The illustrated state is the normal power-producing state of the module (200), though other normal positions and switch configurations may be used. Elements of the control module (205) may be in parallel or in series with the switches (201-204). For example, the control module (205) may contain a relay coil (or other electronics) in series with one or more of the switches (201-204) or a resistor (or other electronics) in parallel with one or more of the switches (201-204). So TEST1 (207) may connect directly or indirectly to the first switch (201), and TESTCOMBINE (206) may connect directly or indirectly to the first switch (201), TEST2 (208) may connect directly or indirectly to the second switch (202), and TESTCOMBINE (206) may connect directly or indirectly to the second switch (202), and so forth. To begin a test sequence, a signal or state change is applied to TESTCOMBINE (206), POSCOMBINE (116), or NEGCOMBINE (114) by an external unit. In one embodiment, TEST1-TEST4 (207-210) are normally at a voltage potential with respect to the ends of the PV array, and TESTCOMBINE (206) is normally floating, so to begin a test sequence, an external unit pulls TESTCOMBINE (206) high or low with respect to TEST1-TEST4 (207-210). In this embodiment the difference in potential between TEST1 (207) and TESTCOMBINE (206) is recognized by the control module (205) and the first switch (201) is closed allowing an external unit to make measurements that reveal the health of the strings, sub-strings, or modules connected to TEST1 (207). When testing on TEST1 (207) is complete, TEST1 (207) floats or the test times out, causing the second switch (202) to close and the first switch (201) to open, directing current exclusively through the TEST2 (208) harness and revealing the health of the strings, sub-strings, or modules connected to TEST2 (208). In turn, when testing on TEST2 (208) is complete, TEST2 (208) floats or the test times out and triggers the third switch (203) to close and the second switch (202) to open, directing current exclusively through the TEST3 (209) test harness. This sequence repeats until the TEST4 (210) test harness floats or the test times out and all the switches return to their normal power-producing state. The switch transitions described above as concurrent events may also be separate events. For example, the second switch (202) may open before or after the third switch (203) is closed. The switches (201-204) may transition when the active test harness floats, or on a fixed or configurable timing schedule that allows sufficient time for each test to occur before the switches progress to the next state. In an alternative embodiment, the control module (205) responds to a state change or signal on TESTCOMBINE (206) by connecting TESTCOMBINE (206) to one or more test harnesses (207-210), then a different one or more test harnesses (207-210), then a different one or more test harnesses (207-210), and so on. The health of the monitored equipment may then be calculated by solving the resulting simultaneous equations. For example, the control module (205) may close the first switch (201), allowing the TEST1 (207) current to be measured, then close the second switch (202), allowing the combined TEST1 (207) and TEST2 (208) current to be measured. Then the first switch (201) may be opened and the third switch (203) closed, allowing the combined TEST2 (208) and TEST3 (209) current to be measured. Then the second switch (202) may be opened and the forth switch (204) closed, allowing the combined TEST3 (209) and TEST4 (210) current to be measured. In an alternative embodiment the switches may be operated and released in any order that allows the individual string currents to be calculated. In yet another alternative embodiment, the control unit (205) may respond to a signal on TESTCOMBINE (206) by connecting TESTCOMBINE (206) to the one or more test harnesses (207-210) indicated by that signal, then return to its normal state after a period of time or after a reset signal. The signal may be analog or digital, discrete or continuous. In yet another embodiment, the control module (205) may respond to a signal on TESTCOMBINE (206) by connecting TESTCOMBINE (206) to the one or more test harnesses (207-210) indicated by that signal, then sequencing the switches (201-204) to one or more additional states (allowing for additional measurements), then returning to the normal state after a period of time or after a reset signal.

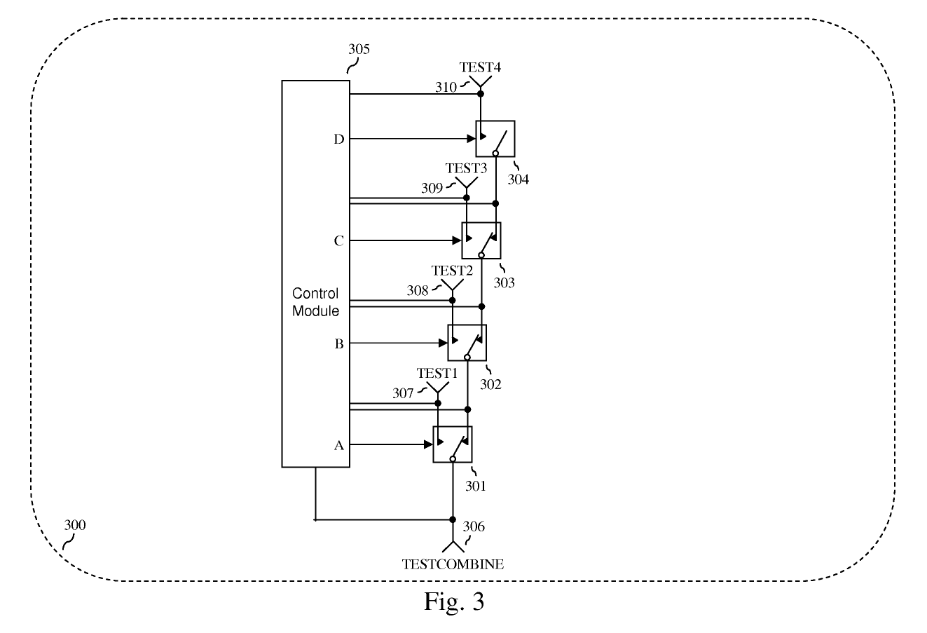

FIG. 3 (300) illustrates a second embodiment of the combiner switching module (101) of FIG. 1. The illustrated state (300) is the normal power-producing state of the module (300) though other normal positions and switch configurations may be used. Elements of the control module (305) may be in parallel (as illustrated) or in series (not illustrated) with the switches (301-304). To begin a test sequence, a signal or change in state is applied to TESTCOMBINE (306) by an external unit. In one embodiment, TEST1-TEST4 (307-310) are normally at a voltage potential with respect to the end of the PV array, and TESTCOMBINE (306) is normally floating, so to begin a test sequence in this embodiment, an external unit pulls TESTCOMBINE (306) high or low with respect to TEST1-TEST4 (307-310). In this embodiment the potential difference between TEST1 (307) and TESTCOMBINE (306) is recognized by the control module (305) and the first switch (301) is operated allowing an external unit to make measurements that reveal the health of the strings, sub-strings, or modules connected to TEST1 (307). When testing on TEST1 (307) is complete TEST1 (307) floats or the test times out, causing the second switch (302) to operate and the first switch (301) to release, directing current exclusively through the TEST2 (308) harness and revealing the health of the string, sub-strings, or individual modules connected to TEST2 (308). In turn, when testing on TEST2 (308) is complete, TEST2 (308) floats or the test times out and triggers the third switch (303) to operate and the second switch (302) to release, directing current exclusively through the TEST3 (309) test harness. This sequence repeats until the TEST4 (310) test harness floats or the last test times out and all the switches are returned to their normal power-producing state. The switch transitions described above as concurrent events may also be separate events. For example, the second switch (302) may release before or after the third switch (303) is operated. The switches may be operated in any order that results in a polling of the test harnesses (307-310). The switches (301-304) may transition when the active test harness floats, or on a fixed or configurable timing schedule that allows sufficient time for each test to occur before the switches progress to the next state. In an alternative embodiment, the control unit (305) may respond to a signal on TESTCOMBINE (306) by connecting TESTCOMBINE (306) to the test harness (or harnesses) indicated by that signal, then return to its normal state after a period of time or after a reset signal. The signal may be analog or digital, discrete or continuous. In yet another embodiment, the control module (305) may respond to a signal on TESTCOMBINE (306) by connecting TESTCOMBINE (306) to the one or more test harnesses (307-310) indicated by that signal, then sequencing the switches to one or more additional states (allowing for additional measurements), then returning to the normal state after a period of time or after a reset signal.

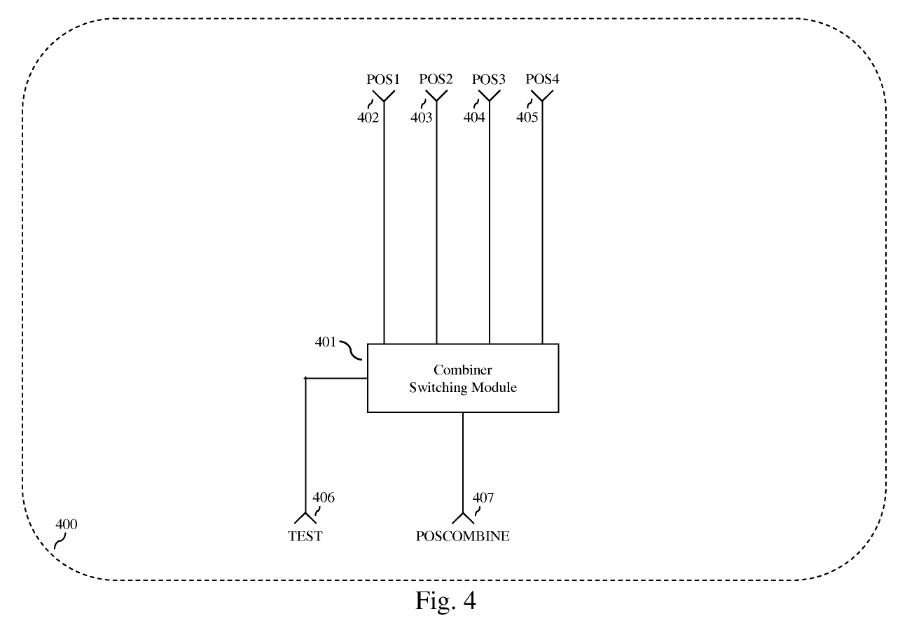

FIG. 4 illustrates a second embodiment of the PV combiner unit (400) of the invention. For convenience of illustration, FIG. 4 shows a unit that consolidates the positive ends of four PV strings (402-405), though this embodiment scales to support any practical number of strings and may combine the negative ends instead of, or in addition to, the positive ends. POSCOMBINE (407) passes consolidated PV current to other PV components, including but not limited to, other PV combiner units of the invention, sensor units of the invention, or other components common in the art. The combiner switching module (401) allows the sensor unit of the invention to test individual PV strings or groups of PV strings when a state change or signal is impressed on TEST (406) or POSCOMBINE (407). The combiner switching module (401) responds to a signal on TEST (406) or POSCOMBINE (407) by connecting TEST (406) to the individual PV string or group of PV strings (402-405) indicated by the signal, or by connecting TEST (406) to a sequential polling of all or some of the PV strings (402-405). Alternatively, the combiner switching module (401) may respond to a signal on TEST (406) or POSCOMBINE (407) by applying an open circuit on one or more of the PV strings (402-405) so that an external sensor unit may measure the health of the remaining strings (402-405). The PV combiner unit (400) may be powered by any means common in the art, including but not limited to, battery power and the power running through the unit. TEST (406) may be comprised of multiple conductors.

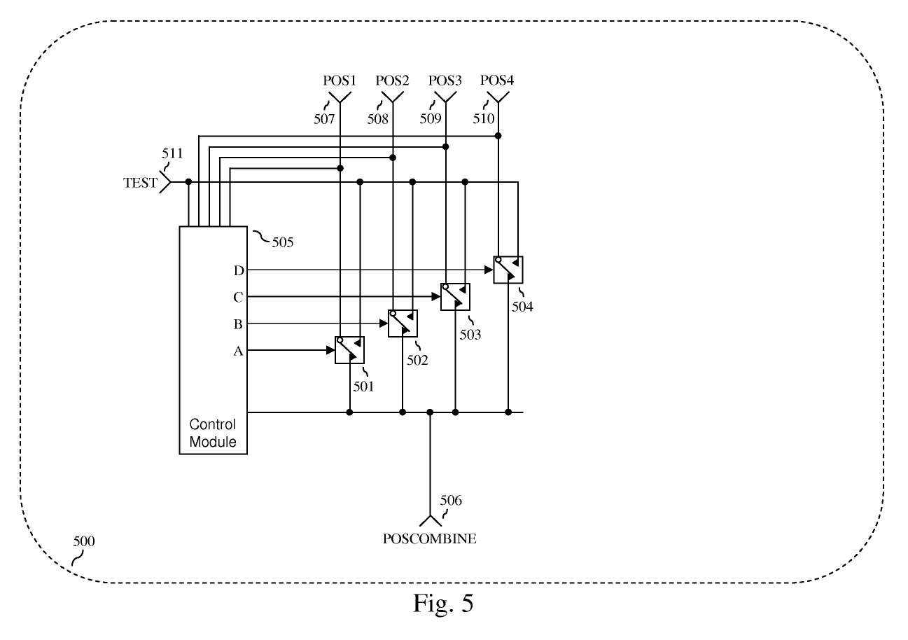

FIG. 5 (500) illustrates a first embodiment of the combiner switching module (401) of FIG. 4. The illustrated state is the normal power-producing state of the module (500), though other switch configurations may be used. Elements of the control module (505) may be in parallel (as illustrated) or in series (not illustrated) with the switches (501-504). To begin a test sequence, a signal or change in state is impressed on TEST (511) by an external unit. In this embodiment, TEST (511) is normally floating and is pulled low or high with respect to POS1-POS4 (507-510) by an external unit. The potential difference between TEST (511) and POSCOMBINE (506) is recognized by the control module (505) and the first switch (501) is operated allowing an external unit to make measurements on TEST (511) that reveal the health of the string, sub-string, or module connected to POS1 (507). After a sufficient measurement time the second switch (502) is operated and the first switch (501) is released, directing current exclusively through POS2 (508) and revealing the health of the string, sub-string, or module connected to POS2 (508). After a sufficient measurement time the third switch (503) is operated and the second switch (502) is released, directing current exclusively through POS3 (509). This polling sequence repeats until the forth switch (504) is released, returning the switches to their normal power-producing state. The switch transitions described above as concurrent events may also be separate events. For example, the second switch (502) may be released before or after the third switch (503) is operated. The switch transitions described above as timed events may instead be controlled by signals on TEST (511). Multiple switches (501-504) may be connected to TEST (511) simultaneously as long as the current rating of the equipment is not exceeded and enough measurements are taken that the health of the monitored equipment can be computed by solving simultaneous equations. In an alternative embodiment, the control module (505) responds to a potential on TEST (511) by connecting TEST (511) to one or more PV conductors (507-510), then a different one or more PV conductors (507-510), then a different one or more PV conductors (507-510), and so on. The health of the monitored equipment may then be calculated by solving the resulting simultaneous equations. For example, the control module (505) may operate the first switch (501), allowing the POS1 (507) current to be measured, then operate the second switch (502), allowing the combined POS1 (507) and POS2 (508) current to be measured. Then the first switch (501) may be released and the third switch (503) operated, allowing the combined POS2 (508) and POS3 (509) current to be measured. Then the second switch (502) may be released and the forth switch (504) operated, allowing the combined POS3 (509) and POS4 (510) current to be measured. In an alternative embodiment the switches may be operated and released in any order that allows the individual string currents to be calculated. In yet another alternative embodiment, the control module (505) may respond to a signal on TEST (511) by connecting TEST (511) to the POS1-POS4 (507-510) conductor or conductors indicated by that signal, then return to its normal state after a period of time or after a reset signal. The signal may be analog or digital, discrete or continuous. In yet another embodiment, the control module (505) may respond to a signal on TEST (511) by connecting TEST (511) to the POS1-POS4 (507-510) conductor or conductors indicated by that signal, then sequencing the switches to one or more additional states (allowing for additional measurements), then returning to the normal state after a period of time or after a reset signal.

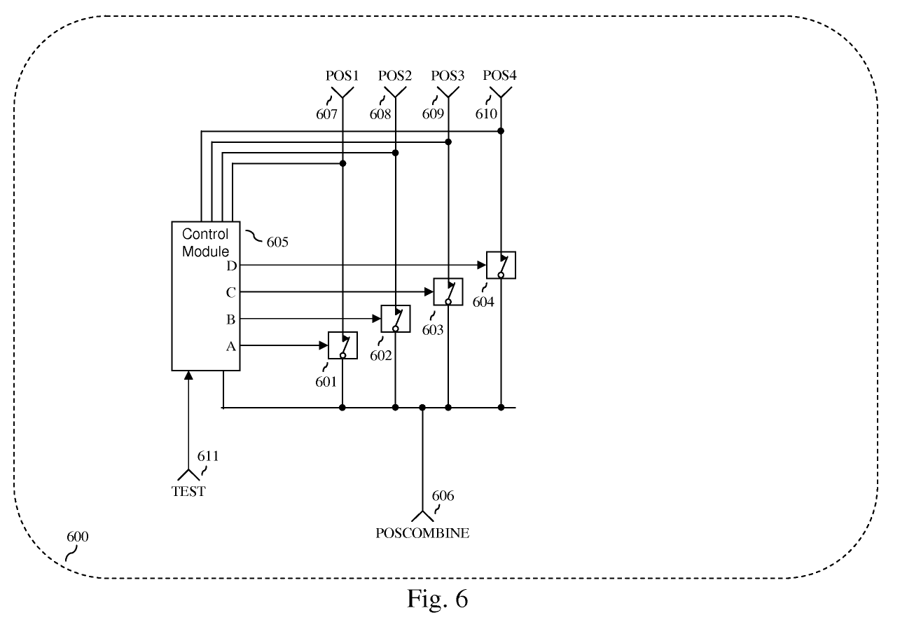

FIG. 6 (600) illustrates a second embodiment of the combiner switching module (401) of FIG. 4. The illustrated state is the normal power-producing state of the module (600), though other switch configurations may be used. One of the illustrated switches (601-604) may be redundant in some embodiments. Elements of the control module (605) may be in parallel (as illustrated) or in series (not illustrated) with the switches (601-604). To begin a test sequence, a signal or change in state is impressed on TEST (611) by an external unit. In one embodiment, TEST (611) is normally floating and is pulled low or high with respect to POS1-POS4 (607-610) by an external unit. In this embodiment, the potential difference between TEST (611) and POSCOMBINE (606) is recognized by the control module (605) and the first switch (601) is operated allowing measurements to be made that reveal the combined health of the strings, sub-strings, or modules connected to POS2-POS4 (608-610). After a sufficient measurement time the second switch (602) is operated and the first switch (601) is released, directing current through POS1 (607), POS3 (609), and POS4 (610) and revealing the health of the strings, sub-strings, or modules connected to those conductors. After a sufficient measurement time the third switch (603) is operated and the second switch (602) is released, directing current through POS1 (607), POS2 (608), and POS4 (610). This polling sequence repeats until the last switch (604) is released, returning the switches to their normal power-producing state. The health of the monitored equipment may then be computed by solving the simulations equations. The switch transitions described above as concurrent events may also be separate events. For example, the second switch (602) may be released before or after the third switch (603) is operated. The switch transitions described above as timed events may instead be controlled by signals on TEST (611). In an alternative embodiment, the control module (605) responds to a potential on TEST (611) by allowing time for the combined POS1-POS4 (607-610) current to be measured, then operating the first switch (601), allowing time for the combined POS2-POS4 (608-610) current to be measured, then operating the second switch (602), allowing time for the combined POS3-POS4 (609-610) current to be measured, then operating the third switch (603), allowing time for the POS4 (610) current to be measured, then releasing all the switches (601-603) to their normal operating positions. The forth switch (604) may be redundant. In an alternative embodiment the switches may be operated and released in any order that allows the individual string currents to be calculated. In yet another alternative embodiment, the control module (605) may respond to a signal on TEST (611) by operating zero, one, or a plurality switches; then releasing zero, one, or a plurality of switches; then operating one or more switches; then releasing one or more switches; and so forth until sufficient data is collected to assess the health of the monitored equipment to the desired level. In yet another alternative embodiment, the control module (605) may respond to a signal on TEST (611) by operating the switches (601-604) indicated by that signal, then return to the normal state after a period of time or after a reset signal. The signal may be analog or digital, discrete or continuous. In still another embodiment, the control module (605) may respond to a signal on TEST (611) by operating the switches (601-604) indicated by that signal, then sequencing the switches to one or more additional states (allowing for additional measurements), then returning to the normal state after a period of time or after a reset signal.

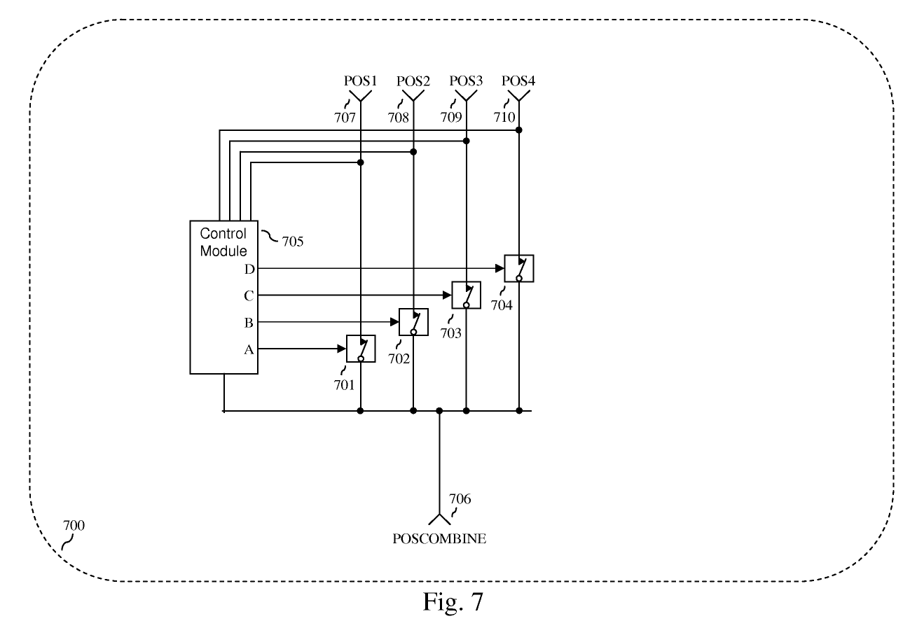

FIG. 7 illustrates a third embodiment of the PV combiner unit (700) of the invention. The illustrated state is the normal power-producing state of the unit (700), though other switch configurations may be used. One of the illustrated switches (701-704) may be redundant in some embodiments. Elements of the control module (705) may be in parallel (as illustrated) or in series (not illustrated) with the switches (701-704). To begin a test sequence in this embodiment, an open circuit, sub-threshold current, alternating current, or non-DC signal may be impressed on POSCOMBINE (706) by an external unit. In an alternative embodiment one or more signals, not normally found in PV generated power, may be impressed on POSCOMBINE (706) by an external unit to begin a test sequence. The control module (705) responds to the signal on POSCOMBINE (706) by applying an open circuit (701-704) on one or more of the PV strings (707-710) so that an external sensor unit may measure the health of the remaining strings (707-710). The control module (705) may open different switches (701-704) in response to different signals on POSCOMBINE (706), or one signal on POSCOMBINE (706) may initiate a switching sequence that opens one or more switches, opens a different one or more switches, and repeats as necessary. The control module (705) may wait a fixed or configurable delay before responding to the signal on POSCOMBINE (706) and may wait a fixed or configurable delay before progressing through each step in any switching sequence. When the test or test sequence is complete the unit returns to its normal power-producing state. Combiner monitoring units with different delay lengths may therefore be installed in an array topology to enabled a polling of the entire array in a timed sequence. The PV combiner unit (700) may be powered by any means common in the art, including but not limited to, battery power and the power running through the unit.

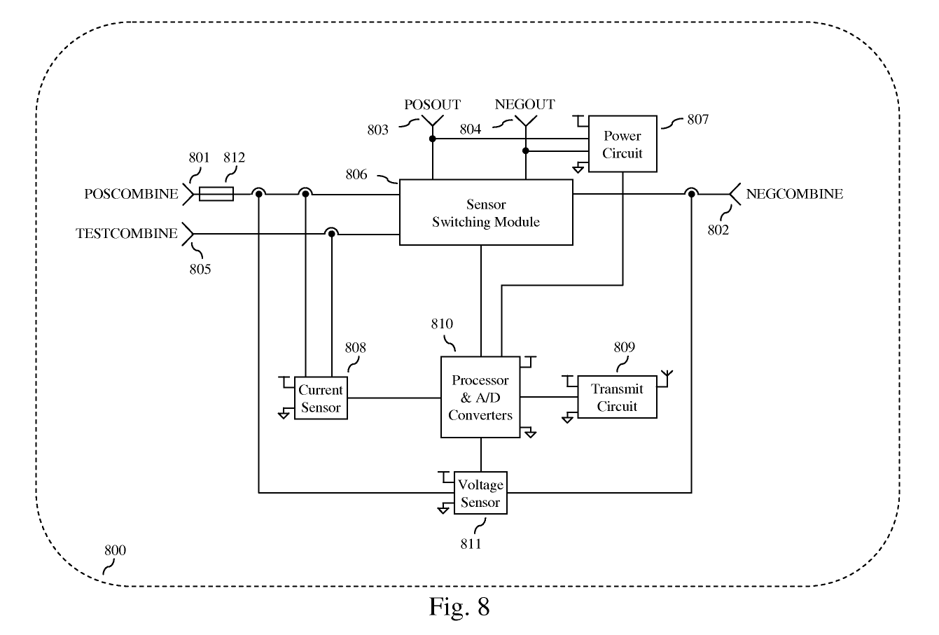

FIG. 8 illustrates a first embodiment of a sensor monitoring unit (800) of the invention. Generated PV power flows in through POSCOMBINE (801) and NEGCOMBINE (802) and out to other PV equipment through POSOUT (803) and NEGOUT (804). During normal power production, TESTCOMBINE (805) floats. During tests, switches in the sensor switching module (806) may be used to impressed current through TESTCOMBINE (805). When enabled, one or more current sensors (808) convert measured currents to digital data and forward the data to a processor (810) for storage, analysis, and transmission (809) to other devices. An optional voltage sensor (811) may be used to measure the operating voltage. One or more optional fuses (812) may be used to provide protection from string faults. A power circuit (807) provides electrical energy and energy management functions common in the art that may include, but are not limited to, mains power, battery power, power conversion, sleep management, electrical isolation, voltage regulation, and battery charging. During tests, the sensor switching module (806) connects TESTCOMBINE (805) to POSCOMBINE (801) or TESTCOMBINE (805) to NEGCOMBINE (802) in order to impress current through TESTCOMBINE (805) which, in turn, directs current through one or more test points in the PV array and may cause switches in the PV array to toggle. As illustrated, this embodiment is used with PV combiner units having one TESTCOMBINE terminal, though this embodiment may be scaled for use with PV combiner units having a plurality of TESTCOMBINE terminals. This embodiment may also be scaled to incorporate a plurality of TESTCOMBINE terminals that may be used to individually control a plurality of PV combiner units. Following data collection, further processing, may be used to perform a linear or non-linear parameter estimation to characterize the tested modules, or relative measurements may be used to assess relative characterizations.

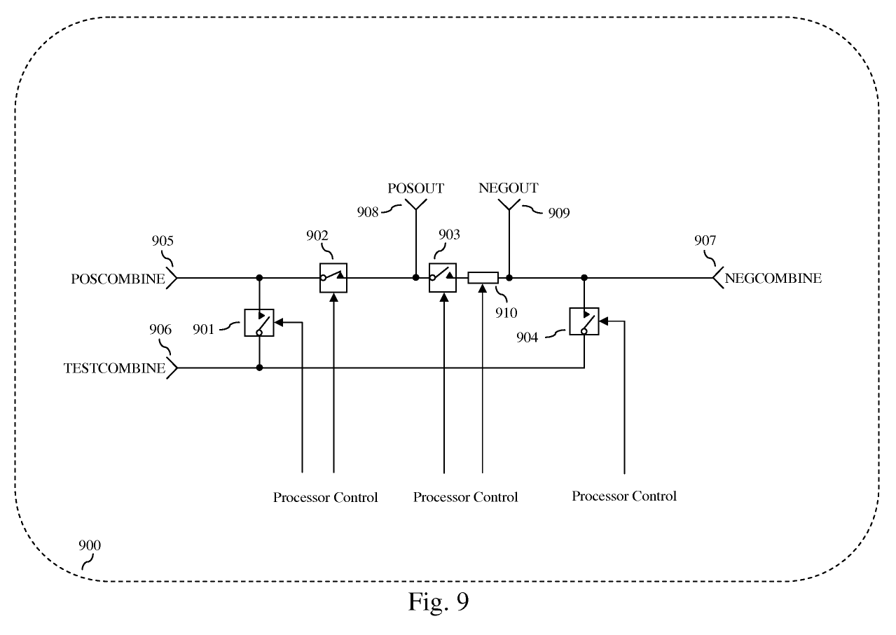

FIG. 9 illustrates one embodiment (900) of the sensor switching module of FIG. 8. Normally open switches (901, 904) leave TESTCOMBINE (906) floating during normal power production but may be closed to connect TESTCOMBINE (906) to POSCOMBINE (905) or NEGCOMBINE (907) in order to create a test circuit through all or part of the array. Current through TESTCOMBINE (906) may also toggle switches in the array in order to alter the topology of the test circuit and thus change the modules being tested. In some configurations both switches (901, 904) are not necessary and one may be eliminated. Other optional switches (902-903) may be used to characterize the test circuit under open-circuit conditions (902) or short-circuit conditions (903). A fixed or variable resistor (910) may be used to add one or more loads while measurements are collected. A switch may also be placed on POSOUT or NEGOUT to isolate the PV power production circuit from any external units that may alter the load during testing. A fixed or variable load may optionally be added on TESTCOMBINE (906). A signal source may optionally be added on TESTCOMBINE (906), POSCOMBINE (905), or NEGCOMBINE (907) in order to impress an optional signal.

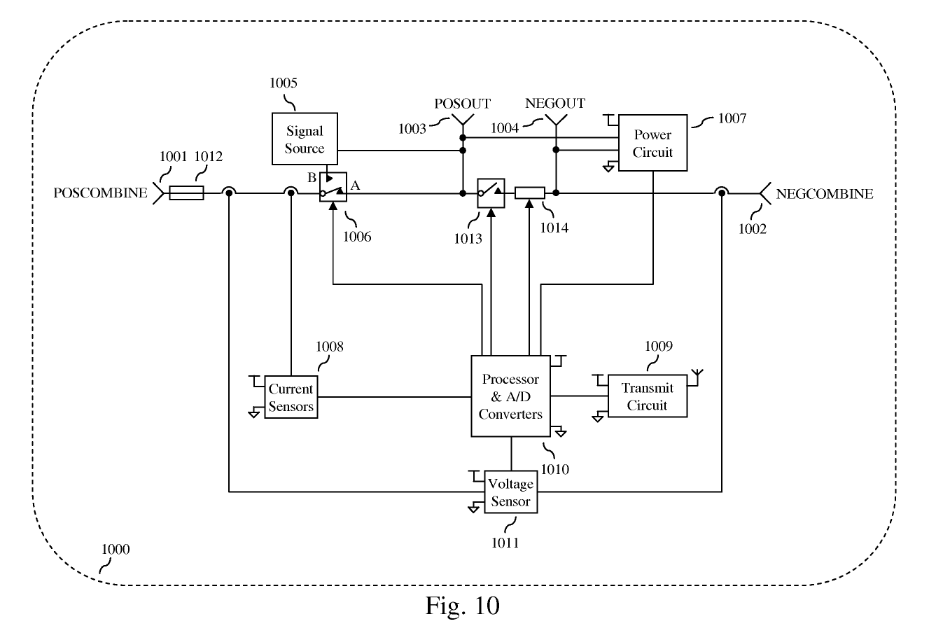

FIG. 10 illustrates a second embodiment of a sensor monitoring unit (1000) of the invention. Generated PV power flows into the unit through POSCOMBINE (1001) and NEGCOMBINE (1002) and out to other PV equipment through POSOUT (1003) and NEGOUT (1004). During normal power production, the signal switch (1006) is in position A. In order to begin a test sequence, the signal switch (1006) is set to position B, impressing a non-DC signal on the PV circuit (1001-1002). One or more PV combiner units in the array may trigger a test or test sequence in response to this signal. The optional short-circuit switch (1013) may be used to perform short circuit testing and the optional fixed or processor controlled resistor (1014) may be used to provide one or more loads while measurements are collected. A switch may also be placed on POSOUT or NEGOUT to isolate the PV power production circuit from any external units that may alter the load during testing. In another embodiment, the signal source (1005) is eliminated and the signal switch impresses an open circuit on POSCOMBINE (1001) to begin a test sequence. In another embodiment one or more TEST junctions, controlled by the processor, may be added to provide a means to control PV combiner units such as FIG. 4 (400).

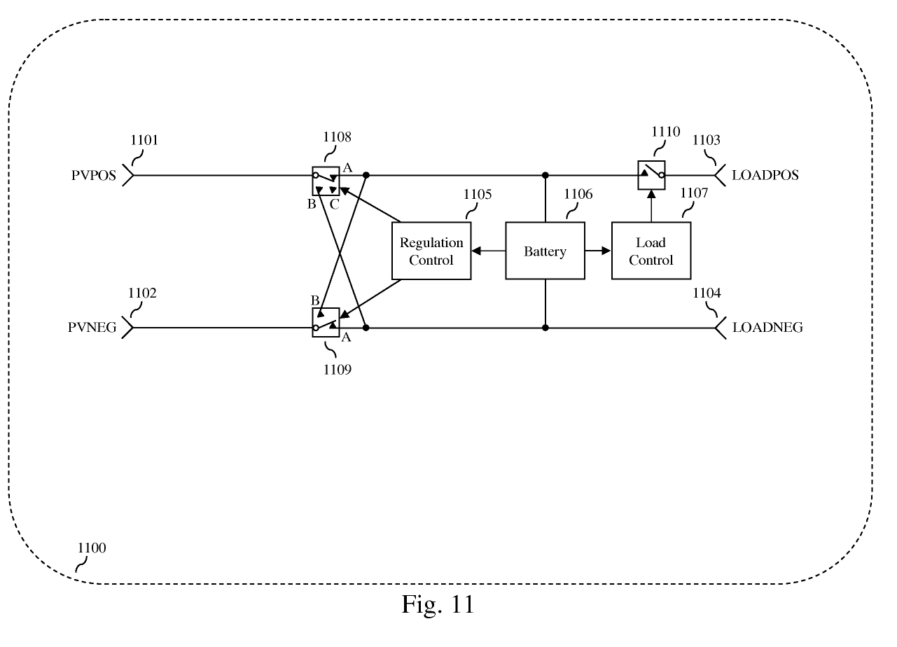

FIG. 11 illustrates a charge controller (1100) of the invention. PVPOS (1101) and PVNEG (1102) pass generated power into the charge controller (1100). LOADPOS (1103) and LOADNEG (1104) pass power to the electrical load. During normal operation, the regulation control (1105) and regulation switches (1108-1109) manage battery (1106) charging, and the load control (1107) and load switch (1110) manage battery (1106) discharging. To perform shunt regulation, one of the regulation switches (1108-1109) may be set to position B in order to shunt the PV supply. Optional switch position C (1108) may be used to perform series regulation. During dark module tests, the regulation switches (1108-1109) may both be set to position A in order to discharge the battery (1106) through the PV supply and test the passive characteristics of the modules in the array. During tests of bypass diodes, the regulation switches (1108-1109) may both be set to position B in order to reverse the battery (1106) through the PV supply and test the characteristics of the bypass diodes in the array. Other switch configurations, diodes, and current control devices may be used to provide the same functionality.

The data produced by the monitoring system of the invention consists of current measurements and, optionally, voltage measurements. These measurements are collected as the topology of the PV installation is altered by one or more switches distributed in the array. Toggling switches cause brief periods of changing current. The system avoids measuring current during these brief periods, or the system post-processes the data to eliminate this type of spurious data. To avoid or post-process spurious data the invention may be configured with a wiring diagram of the installation. Alternatively, the monitoring system of the invention may deduce the wiring diagram by recording data that shows the periods of changing current. Alternatively, the monitoring system of the invention may schedule data sampling to occur after time delays that are long enough to avoid spurious data.

When the sensor monitoring unit of the invention has a TESTCOMBINE junction, then one method of using the monitoring system of the invention begins with the sensor unit impressing a signal on the TESTCOMBINE junction. In one such method, the signal is impressed by connecting the TESTCOMBINE junction to the PV power generation circuit. When a sensor monitoring unit of the invention is connected to a PV combiner unit of the invention via TESTCOMBINE, a signal on TESTCOMBINE causes one or more switches in the PV combiner unit to switch, altering the topology of the PV power generation circuit. In one such method, the topology is altered when some of the current normally flowing through the PV power generation circuit, is directed through TESTCOMBINE. In an alternative method, the topology is altered by one or more open-circuits in the PV power generation circuit.

When the sensor monitoring unit of the invention does not have a TESTCOMBINE junction, then one method of using the monitoring system of the invention begins with the sensor unit impressing an open circuit on POSCOMBINE or NEGCOMBINE. In such a method, the open circuit sets the attached PV combiner units into test mode which in one embodiment causes switches to open on all but one path through each PV combiner unit. Next a load may be applied between POSCOMBINE and NEGCOMBINE and the PV power generation circuit may be isolated from any downstream equipment that may alter the load during testing. After an appropriate delay the open circuit in the sensor unit may be restored. In such a method the sensor monitoring unit then records the current and voltage across a fixed load as switches in the attached PV combiner units close in an orchestrated sequence. This collected data may then be post-processed to determine the passive characteristics of each topology presented by the orchestrated switching sequence. The passive characteristics of each topology may the be processed to calculate the passive characteristics of each string in the PV installation.

When the sensor monitoring unit of the invention does not have a TESTCOMBINE junction, then one method of using the monitoring system of the invention begins with the sensor unit impressing a non-DC signal on the PV power generation circuit. In one such method, the signal is alternating current. When a sensor monitoring unit of the invention is connected to a PV combiner unit of the invention via the PV power generation circuit, a signal on the PV power generation circuit that persists for the requisite period of time causes one or more switches in the PV combiner unit to switch, altering the topology of the PV power circuit. In one such method, the topology is altered by one or more open-circuits in the array.

Switches in this invention may be implemented by a number of means including, but not limited to, electronic, electromechanical, electromagnetic, electro-acoustic or electro-optical switches common in the art. The monitoring system may include lightning surge arrest protection. Some components of the monitoring system may be implemented with electrical isolation from the PV power circuits. The sensor monitoring unit of the invention may be integrated with another PV system component, such as circuit combiner, transformer, disconnect unit, charge controller, fuse box, surge protector, breaker, transfer switch, load center, ground-fault unit, service panel, or inverter.

I do not wish to limit my invention to the examples and illustrations described herein but rather to include such modifications as would be obvious to the ordinary worker skilled in the art of designing PV monitoring systems or measuring the characteristic parameters of photovoltaic modules.

The invention claimed is:

1. A device for controlling the topology of a PV installation, the device comprising: a common terminal, a numbered terminal zero, a numbered terminal one, a switch one having a position one and position two, and a means for actuating said switch one: wherein current flows between the common terminal and both said terminal zero and said terminal one when said switch one is in said position two, and current flows between the common terminal and substantially only said terminal zero when said switch one is in said position one.

2. The device of claim 1, further comprising: n additional terminals numbered 2 to 2+n and n additional switches numbered 2 to 2+n wherein n is any practical number, each said switch having a position one and position two; and a means for individually actuating each said switch: wherein current flows between said common terminal and a given numbered terminal only when said switch of the same number is in position two, and current does not substantially flow between said common terminal and a given numbered terminal when said switch of the same number is in position one.

3. The device of claim 2, wherein said means for individually actuating is a means for means for individually actuating after a delay sufficient to allow measurement of the passive characteristics of the topology prior to actuation.

4. The device of claim 1, wherein said means for actuating is a signal impressed between said terminal zero and said common terminal.

5. The device of claim 4, wherein said signal is a current threshold.

6. The device of claim 4, wherein said signal is a voltage threshold.

7. The device of claim 1, wherein said means for actuating is a means for actuating after a delay sufficient to allow measurement of the passive characteristics of the topology prior to actuation.

8. The device of claim 1, wherein said switch is a thyristor.

9. The method of testing a PV installation, the installation comprising n parallel PV strings wherein each said string is identified by a single unique digital digit in an ordered sequence of n digits wherein n is any practical number greater than one, and the method is comprised of the following steps: applying an substantially open circuit on zero or more of said parallel PV strings wherein each said open circuit is represented in said digital sequence as a 0 and each closed circuit is represented in said digital sequence as a 1; impressing current through the PV installation; measuring a passive electrical characteristic of the PV installation; creating a substantially open circuit on zero or more of said parallel PV strings in which said digital sequence is unique from the digital sequence of any preceding step; impressing current through the PV installation; measuring a passive electrical characteristic the PV installation; repeating steps d, e, and f at least (n−2) times.

10. The method according to claim 9, further comprising the step of: signaling the start of the test sequence.

11. The method according to claim 10, wherein said signaling is an open circuit.

12. The method according to claim 10, wherein said signaling is a sub-threshold current.

13. A battery charge regulator comprising a positive charge source terminal one; a negative charge source terminal two; a positive battery terminal three; a negative battery terminal four; and a first operating mode, wherein: in said first mode, terminal one is connected to terminal three and terminal two is connected to terminal four when the voltage between terminal one and terminal two is exceeded by the voltage between terminal three and terminal four, so that charge is applied from the battery terminals to the charge source terminals.

14. The battery charge regulator of claim 13, further comprising a second operating mode wherein: in said second mode, terminal one is connected to terminal four and terminal two is connected to terminal three when the voltage between terminal one and terminal two is exceeded by the voltage between terminal three and terminal four, so that reverse-polar charge is applied from the battery terminals to the charge source terminals.

15. The battery charge regulator of claim 14, further comprising a third operating mode wherein: in said third mode, terminal one is connected to terminal three and terminal two is connected to terminal four when the voltage between terminal one and terminal two exceeds the voltage between terminal three and terminal four, so that charge is applied from the charge source terminals to the battery terminals.

16. The battery charge regulator of claim 15, further comprising a fourth operating mode wherein: in said fourth mode, no circuit is completed between the battery terminals and the source terminals so substantially no charge is applied between the charge source terminals and the battery terminals.

17. The battery charge regulator of claim 16, wherein said charge source terminals are PV charge source terminals.
